(19) United States
(12) Patent Application Publication
(10) Pub. No.: US 2016/0087094 A1
(43) Pub. Date: Mar. 24, 2016

(54) SEMICONDUCTOR DEVICE

(71) Applicant: Toyota Jidosha Kabushiki Kaisha, Toyota-shi Aichi-ken (JP)

(72) Inventors: Hidefumi Takaya, Toyota-shi Aichi-ken (JP); Jun Saito, Nagoya-shi Aichi-ken (JP); Sachiko Aoi, Nagakute-shi Aichi-ken (JP); Yukihiko Watanabe, Nagakute-shi Aichi-ken (JP); Shoji Mizuno, Okazaki-shi Aichi-ken (JP); Shinichiro Miyahara, Nagoya-shi Aichi-ken (JP)

(21) Appl. No.: 14/853,259

(22) Filed: Sep. 14, 2015

(30) Foreign Application Priority Data
Sep. 19, 2014 (JP) 2014-190810

(51) Int. Cl. H01L 29/78; H01L 29/16; G01R 31/26; H01L 29/06; H01L 27/088; H01L 29/423; H01L 29/04

(52) U.S. Cl. CPC H01L 29/7813; H01L 29/4236; H01L 29/1608; H01L 29/04; H01L 29/0696; H01L 27/088; G01R 31/2621

(57) ABSTRACT

A semiconductor device includes a semiconductor substrate having a main cell region and a sense cell region. A separation trench separating a main second semiconductor region from a sense second semiconductor region is provided in an upper surface of the semiconductor substrate. The semiconductor substrate includes a separation fourth semiconductor region being of a second conductivity type and separated from the main second semiconductor region and the sense second semiconductor substrate by a third semiconductor region.

### CROSS-REFERENCE TO RELATED APPLICATION

This application claims priority to Japanese Patent Application No. 2014-190810 filed on Sep. 19, 2014, the contents of which are hereby incorporated by reference into the present application.

### TECHNICAL FIELD

A technique disclosed in this specification relates to a semiconductor device.

### DESCRIPTION OF RELATED ART

Japanese Patent Application Publication No. 2013-191734 discloses a semiconductor device having a MOSFET. This semiconductor device includes a plurality of gate trenches. A gate insulating film and a gate electrode are formed in each of the trenches. A depletion layer extends in a drift region when the MOSFET is turned off. The extension of the depletion layer in the drift region ensures a dielectric strength of the semiconductor device.

### SUMMARY

Some semiconductor devices may include a main cell region where a main current flows and a sense cell region where a current lower than the current in the main cell region flows. The current flowing in the sense cell region is highly correlated to the current flowing in the main cell region. Thus, the current flowing in the main cell region can be measured by detecting the current flowing in the sense cell region. In this semiconductor device, dielectric strength of a separation region that separates the main cell region and the sense cell region becomes an issue to be considered. This specification is to provide a semiconductor device achieving high dielectric strength in the separation region between the main cell region and the sense cell region.

A semiconductor device disclosed herein comprises: a semiconductor substrate; a main upper electrode disposed on an upper surface of the semiconductor substrate; a sense upper electrode disposed on the upper surface; and a lower electrode disposed on a lower surface of the semiconductor substrate. The semiconductor substrate comprises a main cell region and a sense cell region. The upper surface in the main cell region comprises a main trench. The main trench extends along a first direction from the main cell region to the sense cell region. A main gate insulating layer and a main gate electrode are disposed in the main trench. The main gate electrode is insulated from the semiconductor substrate by the main gate insulating layer. The main cell region comprises: a main first semiconductor region being of a first conductive type and in contact with the main upper electrode and the main gate insulating layer; and a main second semiconductor region being of a second conductive type and in contact with the main gate insulating layer at a lower side of the main first semiconductor region. The upper surface in the sense cell region comprises a sense trench. The sense trench extends along the first direction. A sense gate insulating layer and a sense gate electrode are disposed in the sense trench. The sense gate electrode is insulated from the semiconductor substrate by the sense gate insulating layer. The sense cell region comprises: a sense first semiconductor region being of the first conductive type and in contact with the sense upper electrode and the sense gate insulating layer; and a sense second semiconductor region being of the second conductive type and in contact with the sense gate insulating layer at a lower side of the sense first semiconductor region. A separation trench is provided in the upper surface. The separation trench extends along a second direction different from the first direction and separates the main second semiconductor region from the sense second semiconductor region. A separation insulating layer is disposed in the separation trench. The separation insulating layer is in contact with the main second semiconductor region and the sense second semiconductor region. The semiconductor substrate further comprises a third semiconductor region and a separation fourth semiconductor region. The third semiconductor region is of the first conductive type, disposed across the main cell region and the sense cell region, in contact with the main gate insulating layer at a lower side of the main second semiconductor region, in contact with the sense gate insulating layer at a lower side of the sense second semiconductor region, in contact with the separation insulating layer at a lower side of the main second semiconductor region, and in contact with the separation insulating layer at a lower side of the sense second semiconductor region. The separation fourth semiconductor region is of the second conductive type, in contact with a lower end of the separation insulating layer, and separated from the main second semiconductor region and the sense second semiconductor region by the third semiconductor region.

In this semiconductor device, if elements in the main cell region and an element in the sense cell region turn off, a depletion layer extends from the main second semiconductor region and the sense second semiconductor region into the third semiconductor region. In this semiconductor device, the depletion layer extends further from the separation fourth semiconductor region formed at the lower end of the separation trench into the third semiconductor region surrounding the separation fourth semiconductor region. The presence of the separation fourth semiconductor region facilitates extension of the depletion layer in the vicinity of the separation trench. This allows for high dielectric strength even in the vicinity of the separation trench.

### BRIEF DESCRIPTION OF DRAWINGS

FIG. 1 is a vertical sectional view of a semiconductor device 10 (vertical sectional view taken along line I-I of FIG. 3);

FIG. 2 is a vertical sectional view of the semiconductor device 10 (vertical sectional view taken along line II-II of FIG. 3);

FIG. 3 is a top view of the semiconductor device 10;

FIG. 4 is a vertical sectional view of the semiconductor device 10 (vertical sectional view taken along line IV-IV of FIG. 3);

FIG. 5 is a top view of a semiconductor device according to a second embodiment; and

FIG. 6 is a top view of a semiconductor device according to a third embodiment.

### DETAILED DESCRIPTION

### First Embodiment

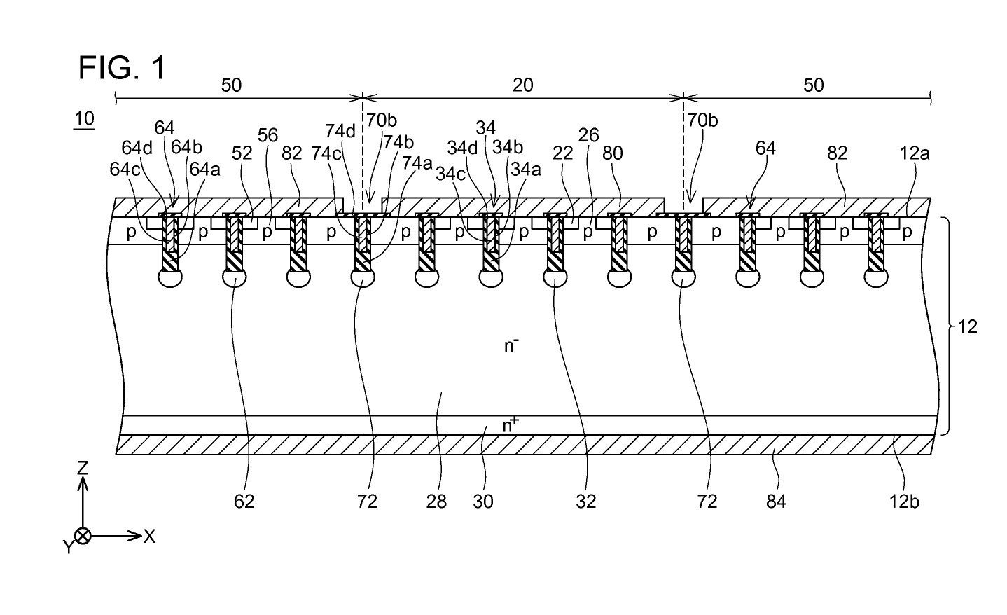

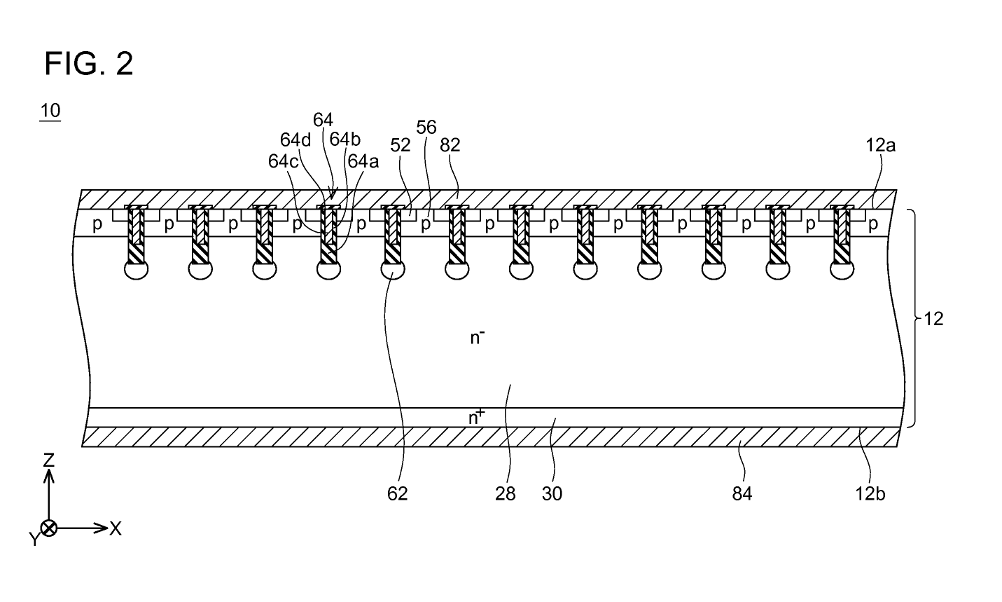

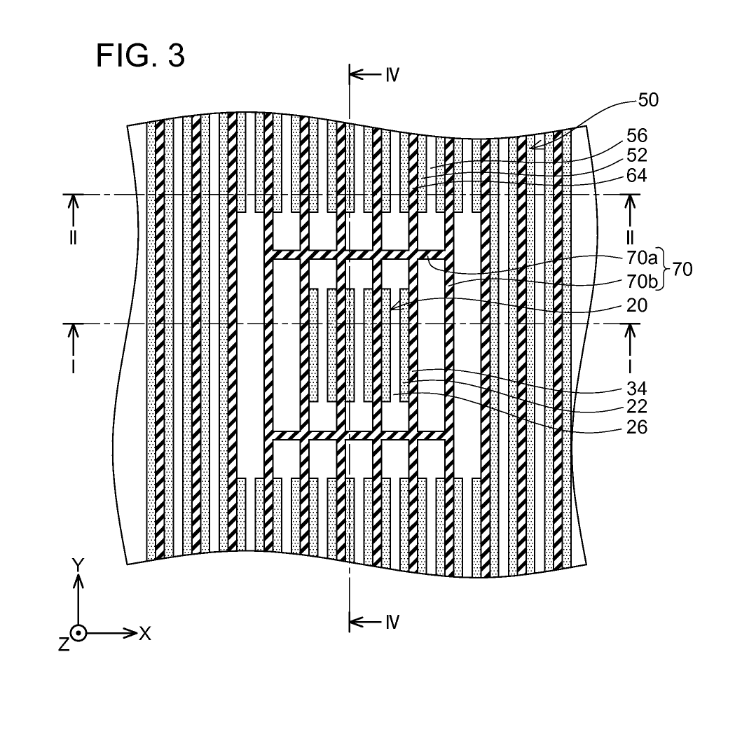

As shown in FIGS. 1 and 2, a semiconductor device 10 according to a first embodiment includes a semiconductor substrate 12, and electrodes, insulating layers and the like formed on an upper surface and a lower surface of the semiconductor substrate 12. FIG. 3 is a top view of the semiconductor device 10. It should be noted that the electrodes and the insulating layers on the semiconductor substrate 12 are not illustrated in FIG. 3. In FIG. 3, to facilitate understanding of the illustration, trenches are hatched with slanted lines and source regions are hatched with dots. As shown in FIG. 3, in a plan view of an upper surface 12a of the semiconductor substrate 12, the semiconductor substrate 12 is separated into a sense cell region 20 and a main cell region 50. The main cell region 50 is a region where a MOSFET structure (more specifically, a source region, a body region, and a gate electrode) is formed. The sense cell region 20 is a region where a MOSFET structure (more specifically, a source region, a body region, and a gate electrode) is formed. The sense cell region 20 has a smaller area than the main cell region 50. The sense cell region 20 and the main cell region 50 are separated by a separation trench 70 extending so as to surround the sense cell region 20. Herein, one direction parallel to the upper surface 12a of the semiconductor substrate 12 is called an X direction (horizontal direction of FIG. 3), another direction parallel to the upper surface 12a of the semiconductor substrate 12 and orthogonal to the X direction is called a Y direction (vertical direction of FIG. 3), and a direction of the thickness of the semiconductor substrate 12 is called a Z direction.

The semiconductor substrate 12 is made of 4H—SiC. The direction of the thickness of the semiconductor substrate 12 (specifically, Z direction) is parallel to the c-axis of a hexagonal crystal. Thus, a plane parallel to the upper surface 12a and a lower surface 12b of the semiconductor substrate 12 (specifically, plane parallel to the X direction and the Y direction) is parallel to the c-plane (specifically, plane parallel to a1-axis, a2-axis, and a3-axis) of the hexagonal crystal.

As shown in FIGS. 1 and 2, a sense source electrode 80 and a main source electrode 82 are formed on the upper surface 12a of the semiconductor substrate 12. The sense source electrode 80 is formed in the sense cell region 20. The sense source electrode 80 covers a substantially entire area of the upper surface 12a in the sense cell region 20. The main source electrode 82 is formed in the main cell region 50. The main source electrode 82 covers a substantially entire area of the upper surface 12a in the main cell region 50. The sense source electrode 80 is separated from the main source electrode 82 at a position above the separation trench 70. A drain electrode 84 is formed on the lower surface 12b of the semiconductor substrate 12. The drain electrode 84 covers a substantially entire area of the lower surface 12b of the semiconductor substrate 12. While not shown in the drawings, a bonding pad is formed in an upper part of the sense source electrode 80. Alternatively, the pad for the sense source electrode 80 may be formed in a different place and may be connected to the sense source electrode 80 via a leading line.

A plurality of trenches 34 is formed in the upper surface 12a of the semiconductor substrate 12 in the sense cell region 20. As shown in FIG. 3, in the plan view of the upper surface 12a of the semiconductor substrate 12, all the trenches 34 extend parallel to each other in the Y direction. As shown in FIG. 1, a bottom insulating layer 34a, a gate insulating film 34b, and a gate electrode 34c are formed in each trench 34. The bottom insulating layer 34a is a thick insulating layer formed at the bottom of the trench 34. A side surface of the trench 34 over the bottom insulating layer 34a is covered with the gate insulating film 34b. The gate electrode 34c is formed in the trench 34 over the bottom insulating layer 34a. The gate electrode 34c is insulated from the semiconductor substrate 12 by the gate insulating film 34b and the bottom insulating layer 34a. The upper surface of the gate electrode 34c is covered with an interlayer insulating film 34d. The gate electrode 34c is insulated from the sense source electrode 80 by the interlayer insulating film 34d.

Source regions 22, a body region 26, a drift region 28, a drain region 30, and bottom regions 32 are formed in the sense cell region 20.

A plurality of source regions 22 is formed in the sense cell region 20. The source regions 22 are each an n-type region. The source regions 22 are formed in a range exposed on the upper surface 12a of the semiconductor substrate 12. The source regions 22 are connected to the sense source electrode 80 through ohmic contact. The source regions 22 contact the gate insulating films 34b.

The body region 26 is formed lateral to and under the source regions 22 and contacts the source regions 22. The body region 26 is a p-type region. The body region 26 is exposed on the upper surface 12a of the semiconductor substrate 12 in a position where the source regions 22 are not formed. The body region 26 is connected to the sense source electrode 80 through ohmic contact. The body region 26 contacts the gate insulating films 34b under a place where the source regions 22 contact the gate insulating films 34b.

The drift region 28 is an n-type region containing a low concentration of n-type impurities. The n-type impurity concentration in the drift region 28 is lower than an n-type impurity concentration in the source region 22. The drift region 28 is formed under the body region 26. The drift region 28 contacts the body region 26 and is separated from the source regions 22 by the body region 26. The drift region 28 contacts the gate insulating films 34b under places where the body region 26 contacts the gate insulating films 34b.

The drain region 30 is an n-type region containing a high concentration of n-type impurities. The n-type impurity concentration in the drain region 30 is higher than the n-type impurity concentration in the drift region 28. The drain region 30 is formed under the drift region 28. The drain region 30 contacts the drift region 28 and is separated from the body region 26 by the drift region 28. The drain region 30 is formed in a range exposed on the lower surface 12b of the semiconductor substrate 12. The drain region 30 is connected to the drain electrode 84 through ohmic contact.

The bottom regions 32 are a p-type regions. Each of the bottom regions 32 is formed in a range contacting a bottom surface of each trench 34 (specifically, the lower end of the bottom insulating layer 34a). In the plan view of the upper surface 12a of the semiconductor substrate 12 as shown in FIG. 3, each of the bottom regions 32 extends along the trench 34. As shown in FIG. 1, each of the bottom regions 32 is surrounded by the drift region 28. All the bottom regions 32 are separated from each other by the drift region 28. Each of the bottom regions 32 is separated from the body region 26 by the drift region 28.

As shown in FIGS. 1 and 2, a plurality of trenches 64 is formed in the upper surface 12a of the semiconductor substrate 12 in the main cell region 50. As shown in FIG. 3, in the plan view of the upper surface 12a of the semiconductor substrate 12, all the trenches 64 extend parallel to each other in the Y direction. As shown in FIGS. 1 and 2, like in each trench 34, a bottom insulating layer 64a, a gate insulating film 64b, and a gate electrode 64c are formed in each trench 64. The bottom insulating layer 64a is a thick insulating layer formed at the bottom of the trench 64. A side surface of the trench 64 over the bottom insulating layer 64a is covered with the gate insulating film 64b. The gate electrode 64c is formed in the trench 64 over the bottom insulating layer 64a. The gate electrode 64c is insulated from the semiconductor substrate 12 by the gate insulating film 64b and the bottom insulating layer 64a. The upper surface of the gate electrode 64c is covered with an interlayer insulating film 64d. The gate electrode 64c is insulated from the main source electrode 82 by the interlayer insulating film 64d.

As shown in FIG. 3, each trench 64 adjacent to the sense cell region 20 in the Y direction is connected to its corresponding trench 34 in the sense cell region 20. Specifically, the trench 34 and the trench 64 are connected to form a linear trench.

As shown in FIGS. 1 and 2, source regions 52, a body region 56, the drift region 28, the drain region 30, and bottom regions 62 are formed in the main cell region 50.

A plurality of source regions 52 is formed in the main cell region 50. The source regions 52 in the main cell region 50 are formed in substantially the same way as the source regions 22 in the sense cell region 20. Specifically, the source regions 52 are each an n-type region. The source regions 52 are formed in a range exposed on the upper surface 12a of the semiconductor substrate 12. The source regions 52 are connected to the main source electrode 82 through ohmic contact. The source regions 52 contact the gate insulating films 64b.

The body region 56 in the main cell region 50 is formed in substantially the same way as the body region 26 in the sense cell region 20. Specifically, the body region 56 is formed lateral to and under the source regions 52 and contacts the source regions 52. The body region 56 is a p-type region. The body region 56 is exposed on the upper surface 12a of the semiconductor substrate 12 in a position where the source regions 52 are not formed. The body region 56 is connected to the main source electrode 82 through ohmic contact. The body region 56 contacts the gate insulating films 64b under a place where the source regions 52 contact the gate insulating films 64b.

The aforementioned drift region 28 is also formed in the main cell region 50. Specifically, the drift region 28 is disposed across the sense cell region 20 and the main cell region 50. The n-type impurity concentration in the drift region 28 is lower than an n-type impurity concentration in the source region 52. The drift region 28 is formed under the body region 56. The drift region 28 contacts the body region 56 and is separated from the source regions 52 by the body region 56. The drift region 28 contacts the gate insulating films 64b under a place where the body region 56 contacts the gate insulating films 64b.

The aforementioned drain region 30 is also formed in the main cell region 50. Specifically, the drain region 30 is disposed across the sense cell region 20 and the main cell region 50. The drain region 30 is also connected to the drain electrode 84 in the main cell region 50.

The bottom regions 62 in the main cell region 50 are p-type regions. The bottom regions 62 are formed in substantially the same way as the bottom regions 32 in the sense cell region 20. Specifically, each of the bottom regions 62 is formed in a range contacting a bottom surface of each trench 64 (specifically, the lower end of the bottom insulating layer 64a). In the plan view of the upper surface 12a of the semiconductor substrate 12 as shown in FIG. 3, the bottom regions 62 extend along the trenches 64. As shown in FIGS. 1 and 2, each of the bottom regions 62 is surrounded by the drift region 28. All the bottom regions 62 are separated from each other by the drift region 28. Each of the bottom regions 62 is separated from the body region 56 by the drift region 28.

As shown in FIG. 3, the separation trench 70 is formed into a ring-shaped rectangular shape surrounding the sense cell region 20. The separation trench 70 has first separation trenches 70a extending in the X direction and second separation trenches 70b extending in the Y direction.

As shown in FIGS. 1, 2, and 4, like in each trench 34, a bottom insulating layer 74a, a gate insulating film 74b, and a gate electrode 74c are formed in the separation trench 70. The bottom insulating layer 74a is a thick insulating layer formed at the bottom of the separation trench 70. A side surface of the separation trench 70 over the bottom insulating layer 74a is covered with the gate insulating film 74b. The gate electrode 74c is formed in the separation trench 70 over the bottom insulating layer 74a. The gate electrode 74c is insulated from the semiconductor substrate 12 by the gate insulating film 74b and the bottom insulating layer 74a. The upper surface of the gate electrode 74c is covered with an interlayer insulating film 74d.

As shown in FIG. 3, the first separation trenches 70a separate the sense cell region 20 and the main cell region 50 adjacent to the Y direction. Each of the first separation trenches 70a crosses the linear trenches formed of the trenches 34 and the trenches 64. Specifically, each of the first separation trenches 70a is connected to the trenches 34 and the trenches 64. The second separation trenches 70b separate the sense cell region 20 and the main cell region 50 adjacent to the X direction. Each trench 34, 64, and 70b are distanced by the substantially same distance in the X direction. Each of the second separation trenches 70b is connected to its corresponding trenches 64. At each of connection points of the separation trench 70, the trench 34, and the trench 64, the bottom insulating layers 34a, 64a, and 74a are connected to each other, the gate electrodes 34c, 64c, and 74c are connected to each other, and the interlayer insulating films 34d, 64d, and 74d are connected to each other. The gate insulating films 34b, 64b, and 74b cover the respective inner surfaces of trenches 34, 64, and 70 so as to insulate the gate electrodes 34c, 64c, and 74c respectively from the semiconductor substrate 12.

As shown in FIGS. 1, 2, and 4, the gate insulating film 74b in the separation trench 70 near the sense cell region 20 contacts the body region 26 in the sense cell region 20. The gate insulating film 74b in the separation trench 70 near the main cell region 50 contacts the body region 56 in the main cell region 50. Specifically, the separation trench 70 separates the body region 26 from the body region 56. The drift region 28 contacts the gate insulating film 74b in the separation trench 70 under places where the body regions 26 and 56 contact the gate insulating film 74b. A source region is not formed in a positon adjacent to the separation trench 70.

A bottom region 72 is formed in a range contacting a bottom surface of the separation trench 70 (specifically, the lower end of the bottom insulating layer 74a). The bottom region 72 is a p-type region. In the plan view of the upper surface 12a of the semiconductor substrate 12 as shown in FIG. 3, the bottom region 72 extends along the separation trench 70. As shown in FIGS. 1, 2, and 4, the bottom region 72 is surrounded by the drift region 28. The bottom region 72 is separated from the other bottom regions 32 and 62 by the drift region 28. The bottom region 72 is separated from the body regions 26 and 56 by the drift region 28. At the connection point of the separation trench 70, the trench 34, and the trench 64, the bottom regions 32, 62, and 72 are connected to each other.

The operation of the semiconductor device 10 is described next. To operate the semiconductor device 10, a potential higher than those of the main source electrode 82 and the sense source electrode 80 is applied to the drain electrode 84. Further, a potential equal to or higher than a threshold is applied to the gate electrodes 34c and 64c, thereby turning on the MOSFET in the sense cell region 20 and the MOSFET in the main cell region 50. More specifically, in the sense cell region 20, a channel is formed in the body region 26 in a range contacting the gate insulating film 34b. This causes electrons to flow from the sense source electrode 80 to the drain electrode 84 via the source region 22, the channel, the drift region 28, and the drain region 30. In the main cell region 50, a channel is formed in the body region 56 in a range contacting the gate insulating film 64b. This causes electrons to flow from the main source electrode 82 to the drain electrode 84 via the source region 52, the channel, the drift region 28, and the drain region 30. A source region is not formed in a position contacting the gate insulating film 74b in the separation trench 70. Thus, in the vicinity of the separation trench 70, electrons flow neither in the sense cell region 20 nor in the main cell region 50. This suppresses flow of electrons from the source region 22 in the sense cell region 20 to the drift region 28 in the main cell region 50 and flow of electrons from the source region 52 in the main cell region 50 to the drift region 28 in the sense cell region 20. Specifically, interference of currents between the main cell region 50 and the sense cell region 20 is suppressed. In the semiconductor device 10, the deep separation trench 70 separates the sense cell region 20 and the main cell region 50 and functions to suppress interference of the currents. Suppressing interference of the currents in this way makes it possible to stabilize a ratio between the current in the main cell region 50 and that in the sense cell region 20. Thus, by detecting the current flowing in the sense cell region 20, the current flowing in the main cell region 50 can be measured correctly.

Reducing the potential applied to the gate electrodes 34c and 64c to a potential less than the threshold eliminates the channels, thereby turning off the MOSFET in the sense cell region 20 and the MOSFET in the main cell region 50. Then, a depletion layer extends into the drift region 28 from a pn junction at a boundary between the body regions 26, 56 and the drift region 28.

In the sense cell region 20, the depletion layer extending from the body region 26 into the drift region 28 reaches the bottom regions 32. Then the depletion layer further extends from each bottom region 32 into the drift region 28. Thus, the drift region 28 between two bottom regions 32 is depleted effectively. This suppresses electric field concentration in the sense cell region 20.

In the main cell region 50, the depletion layer extending from the body region 56 into the drift region 28 reaches the bottom regions 62. Then the depletion layer further extends from each bottom region 62 into the drift region 28. Thus, the drift region 28 between two bottom regions 62 is depleted effectively. This suppresses electric field concentration in the main cell region 50.

In the vicinity of the second separation trench 70b shown in FIG. 1, the depletion layer extending from the body region 26 into the drift region 28 in the sense cell region 20 and the depletion layer extending from the body region 56 into the drift region 28 in the main cell region 50 reach the bottom region 72 at the lower end of the second separation trench 70b. Then the depletion layer further extends from the bottom region 72 into the drift region 28. This effectively depletes the drift region 28 between the bottom region 72 at the lower end of the second separation trench 70b and the bottom region 32 in the sense cell region 20 and the drift region 28 between the bottom region 72 at the lower end of the second separation trench 70b and the bottom region 62 in the main cell region 50. As a result, electric field concentration is suppressed in the vicinity of the second separation trench 70b.

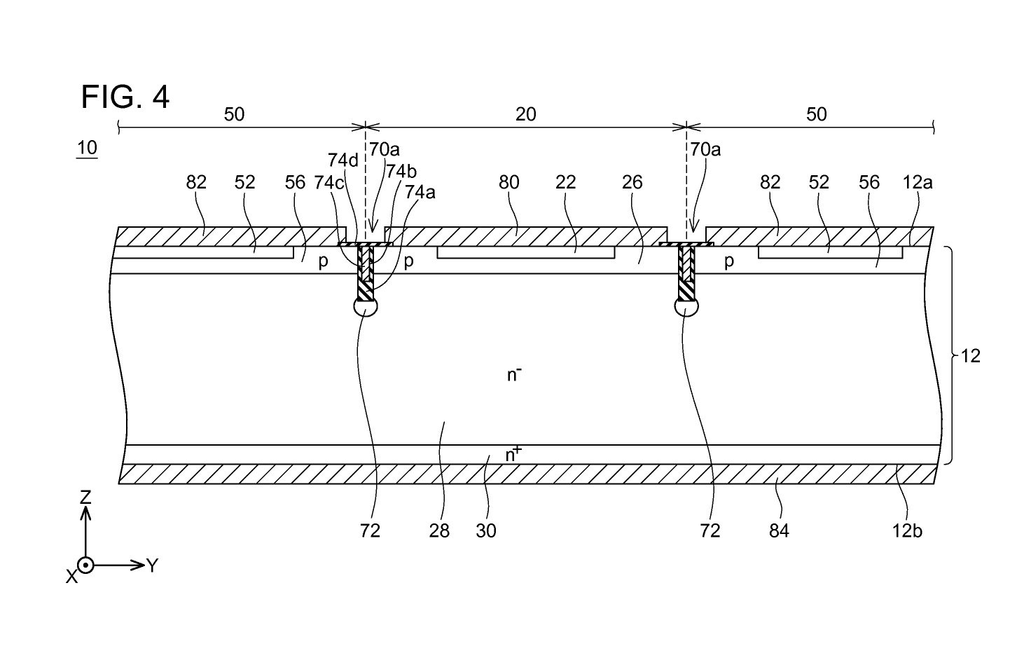

In the vicinity of the first separation trench 70a shown in FIG. 4, the depletion layer extending from the body region 26 into the drift region 28 in the sense cell region 20 and the depletion layer extending from the body region 56 into the drift region 28 in the main cell region 50 reach the bottom region 72 at the lower end of the first separation trench 70a. Then the depletion layer further extends from the bottom region 72 into the drift region 28. This effectively depletes the drift region 28 between the bottom region 72 at the lower end of the first separation trench 70a and the bottom region 32 in the sense cell region 20 and the drift region 28 between the bottom region 72 at the lower end of the first separation trench 70a and the bottom region 62 in the main cell region 50. As a result, electric field concentration is suppressed in the vicinity of the first separation trench 70a.

As described above, in the semiconductor device 10, electric field concentration is suppressed in the sense cell region 20, in the main cell region 50, and in the vicinity of the separation trench 70. This allows for high dielectric strength of the semiconductor device 10.

As described above, in the semiconductor device 10, the separation trench 70 and the bottom region 72 are formed at a boundary between the sense cell region 20 and the main cell region 50. The presence of the bottom region 72 facilitates extension of a depletion layer in the vicinity of the separation trench 70, so that dielectric strength can be enhanced in the vicinity of the separation trench 70. In particular, the separation trench 70 and the bottom region 72 are formed so as to surround the sense cell region 20. This works to enhance dielectric strength at the boundary in an entire area surrounding the sense cell region 20. In particular, the area of the sense cell region 20 is small. This makes a curvature small at a corner of the sense cell region 20 (specifically, in the vicinity of a connection point of the first and second separation trenches 70a and 70b), so that an electric field is likely to be concentrated particularly in the vicinity of the corner. The aforementioned structure can facilitate extension of a depletion layer even in the corner where an electric field is likely to be concentrated, thereby suppressing electric field concentration on the corner. As described above, the semiconductor substrate 12 is made of SiC of a thickness in a direction (Z direction) agreeing with the c-axis. The insulation breakdown electric field of SiC is higher in the c-axis direction than in the a-axis direction (direction orthogonal to the c-axis, specifically lateral direction of the semiconductor substrate 12). Specifically, the semiconductor substrate 12 is susceptible to an electric field in the lateral direction (X direction and Y direction). However, in the semiconductor device 10, the presence of the bottom region 72 at the lower end of the separation trench 70 facilitates extension of a depletion layer in the lateral direction in the vicinity of the separation trench 70. This allows for the high dielectric strength even in the lateral direction. Specifically, the structure enhancing dielectric strength using the bottom region 72 works particularly effectively for a SiC substrate.

The aforementioned separation structure including the separation trench 70 and the bottom region 72 can be formed in an extremely narrow space. This allows size reduction of the semiconductor device 10.

In the semiconductor device 10, the separation trench 70 and the bottom region 72 are formed so as to surround the sense cell region 20. If the dielectric strength in the X direction does not become a serious issue, formation of the second separation trench 70b may be omitted while the first separation trench 70a is formed. The second separation trench 70b can be replaced by a different structure that separates the sense cell region 20 and the main cell region 50. The bottom region 72 may be formed only at the lower end of the first separation trench 70a.

In the aforementioned semiconductor device 10, each trench 34 in the sense cell region 20 and each trench 64 in the main cell region 50 are connected to form a linear pattern and each gate electrode 34c and each gate electrode 64c are connected across the sense cell region 20 and the main cell region 50. This allows a gate voltage in the sense cell region 20 and a gate voltage in the main cell region 50 to be controlled simultaneously. Since the gate electrodes 34c and 64c are connected in the trench, a wire for connecting the gate electrodes 34c and 64c is not required on the upper surface 12a of the semiconductor substrate 12. This prevents the occurrence of drop of a breakdown voltage to be caused by the wire.

In the aforementioned semiconductor device 10, a source region is not formed in a position contacting the separation trench 70. Further, a source region is not formed in a position contacting a side surface on the separation trench 70 side of the trench 34 next to the separation trench 70 and in a position contacting a side surface on the separation trench 70 side of the trench 64 next to the separation trench 70. Not forming a source region in the vicinity of the separation trench 70 can suppress interference of currents between the sense cell region 20 and the main cell region 50. If interference of the currents does not become a serious issue, a source region may be formed in each of these positions.

In the aforementioned semiconductor device 10, the gate electrode 74c is formed in the separation trench 70. Forming the gate electrode 74c in the separation trench 70 extends a depletion layer more easily from the bottom region 72 toward its surrounding area. This structure forms the same structure in the separation trench 70 as that formed in the trenches 34 and the trenches 64. Thus, the structure in the separation trench 70 can be formed simultaneously with the structure in the trenches 34 and the trenches 64. As a result, the semiconductor device 10 can be manufactured efficiently. Alternatively, according to a different embodiment, a gate electrode is not always required to be formed in the separation trench 70. As an example, an insulating layer may fill the inside of the separation trench 70 entirely.

In the aforementioned semiconductor device 10, a MOSFET is formed in each of the sense cell region 20 and the main cell region 50. Alternatively, an IGBT may be formed in each of these regions. An IGBT can be formed by replacing the aforementioned drain region 30 with a p-type collector region.

In the aforementioned semiconductor device 10, the p-type region and the n-type region may be arranged in opposite ways. In this case, the MOSFET in each of the sense cell region 20 and the main cell region 50 becomes a p-channel MOSFET.

### Second Embodiment

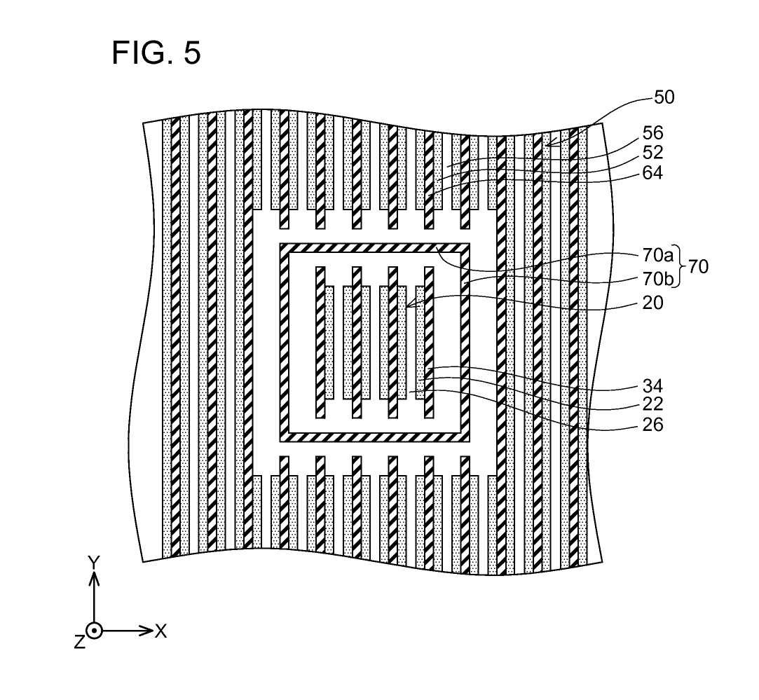

FIG. 5 is a top view corresponding to FIG. 1 and showing a semiconductor device of a second embodiment. The semiconductor device of the second embodiment differs from the semiconductor device 10 of the first embodiment in that the separation trench 70 is separated from the trenches 34 and the trenches 64. The structure of the semiconductor device of the second embodiment in other respects is the same as that of the semiconductor device 10 of the first embodiment.

As shown in FIG. 5, in the semiconductor device of the second embodiment, the trenches 34 in the sense cell region 20 are separated from the trenches 64 in the main cell region 50. Specifically, the gate electrodes 34c in the sense cell region 20 are separated from the gate electrodes 64c in the main cell region 50. The separation trench 70 is separated from both the trenches 34 in the sense cell region 20 and the trenches 64 in the main cell region 50. Even in this structure, similarly to the aforementioned first embodiment, the presence of the bottom region 72 at the lower end of the separation trench 70 can still facilitate extension of a depletion layer in the vicinity of the separation trench 70. The structure of FIG. 5 may be changed such that the separation trench 70 is connected to either the trenches 34 or the trenches 64.

### Third Embodiment

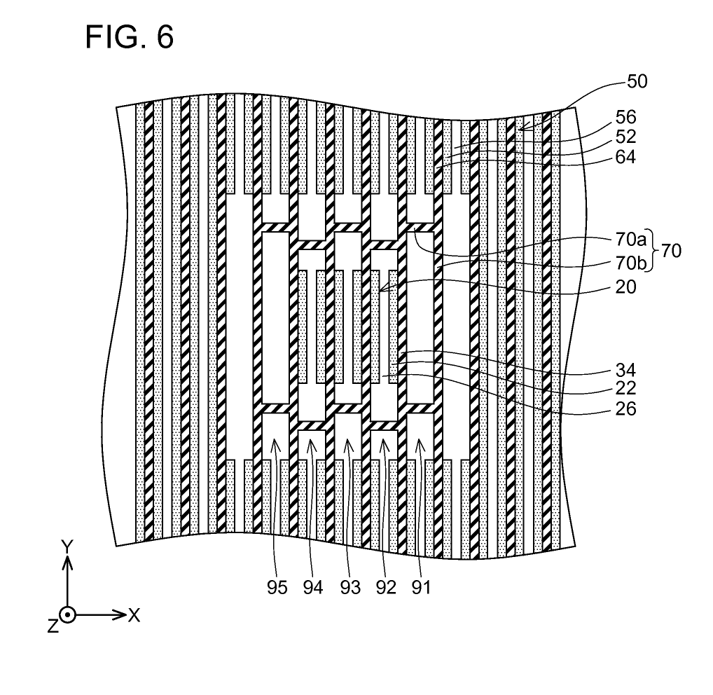

FIG. 6 is a top view corresponding to FIG. 1 and showing a semiconductor device of a third embodiment. In the semiconductor device of the third embodiment, the arrangement of the first separation trench 70a seen from the upper surface differs from that in the semiconductor device 10 of the first embodiment. The structure of the semiconductor device of the third embodiment in other respects is the same as that of the semiconductor device 10 of the first embodiment.

As shown in FIG. 6, in the semiconductor device of the third embodiment, the first separation trench 70a extends while shifting its position in the Y direction. Each of a region 91, a region 92, a region 93, a region 94, and a region 95 described below is a region held between trenches in the sense cell region 20. The first separation trench 70a in the odd-numbered regions 91, 93, and 95 as counted from the right side of FIG. 6 shifts to a more upper position of FIG. 6 than the first separation trench 70a in the even-numbered regions 92 and 94. Thus, a position where the first separation trench 70a in each of the odd-numbered regions 91, 93, and 95 crosses each trench 34, 64 extending in the Y direction differs from a position where the first separation trench 70a in each of the even-numbered regions 92 and 94 crosses each trench 34, 64 extending in the Y direction. Specifically, the first separation trench 70a crosses trenches 34, 64 at a three-way intersection, not a four-way intersection. This structure can suppress the occurrence of a processing failure at the intersection during formation of the trenches. As an example, this can suppress the occurrence of a phenomenon of deep trenches being formed locally at the intersection while the trench is formed by etching.

The following describes a relationship between the aforementioned semiconductor devices of the embodiments and a semiconductor device of the Claims. The trench 64 of the embodiments is an example of a main trench of the Claims. The gate insulating film 64b and the bottom insulating layer 64a of the embodiments are an example of a main gate insulating layer of the Claims. The gate electrode 64c of the embodiments is an example of a main gate electrode of the Claims. The source region 52 of the embodiments is an example of a main first semiconductor region of the Claims. The body region 56 of the embodiments is an example of a main second semiconductor region of the Claims. The trench 34 of the embodiments is an example of a sense trench of the Claims. The gate insulating film 34b and the bottom insulating layer 34a of the embodiments are an example of a sense gate insulating layer of the Claims. The gate electrode 34c of the embodiments is an example of a sense gate electrode of the Claims. The source region 22 of the embodiments is an example of a sense first semiconductor region of the Claims. The body region 26 of the embodiments is an example of a sense second semiconductor region of the Claims. The first separation trench 70a of the embodiments is an example of a separation trench of the Claims. The separation trench 70 of the embodiments is an example of a ring- shaped trench of the Claims. The gate insulating film 74b and the bottom insulating layer 74a are an example of a separation insulating layer of the Claims. The drift region 28 and the drain region 30 of the embodiments are an example of a third semiconductor region of the Claims. The bottom region 62 of the embodiments is an example of a main fourth semiconductor region of the Claims. The bottom region 32 of the embodiments is an example of a sense fourth semiconductor region of the Claims. The bottom region 72 of the embodiments is an example of a separation fourth semiconductor region of the Claims. The Y direction of the embodiments is an example of a first direction of claim 1. The X direction of the embodiments is an example of a second direction of the Claims.

The structures of the aforementioned semiconductor devices of the embodiments can be expressed as follows.

The semiconductor substrate may further comprise a main fourth semiconductor region and a sense fourth semiconductor region. The main fourth semiconductor region may be of the second conductive type, in contact with a lower end of the main gate insulating layer, and separated from the main second semiconductor region by the third semiconductor region. The sense fourth semiconductor region may be of the second conductive type, in contact with a lower end of the sense gate insulating layer, and separated from the sense second semiconductor region by the third semiconductor region.

In this structure, the presence of the separation fourth semiconductor region, the main fourth semiconductor region, and the sense fourth semiconductor region can extend a depletion layer effectively in the third semiconductor region. This can increase the dielectric strength of the semiconductor device further.

A ring-shaped trench may be formed on the upper surface of the semiconductor substrate. The ring-shaped trench may extend so as to surround the sense cell region. An insulating layer may be disposed in the ring-shaped trench. The semiconductor substrate may further comprise a ring-shaped semiconductor region being of the second conductive type, being in contact with a lower end of the insulating layer in the ring-shaped trench, and extending along the ring-shaped trench. The separation trench may be a part of the ring-shaped trench. The separation insulating layer may be a part of the insulating layer in the ring-shaped trench. The separation fourth semiconductor region may be a part of the ring-shaped semiconductor region.

This structure can suppress electric field concentration in an entire area surrounding the sense cell region.

The main trench, the sense trench and the separation trench may be connected to each other. The main gate electrode and the sense gate electrode may be connected to each other.

This structure can control the main gate electrode and the sense gate electrode simultaneously.

The semiconductor substrate may be a SiC substrate having a hexagonal crystal structure having a c-axis extending along a thickness direction of the semiconductor substrate.

This structure can enhance dielectric strength in the lateral direction of the semiconductor substrate in which the semiconductor substrate is susceptible to an electric field.

A structure, in which a semiconductor region being of the first conductive type and exposed on the upper surface is not disposed at a position being in contact with the separation insulating layer, may be adopted.

This structure can suppress interference of currents between the sense cell region and the main cell region.

An electrode insulated from the semiconductor substrate by the separation insulating layer may be disposed in the separation trench.

This structure can facilitate extension of a depletion layer from the separation fourth semiconductor region.

The semiconductor device may comprise a plurality of the main trenches and a plurality of the sense trenches. The plurality of the main trenches and the plurality of the sense trenches may be connected to each other to form a plurality of linear trenches. The plurality of the linear trenches may include: a first linear trench; a second linear trench adjacent to the first linear trench; and a third linear trench adjacent to the second linear trench. The separation trench may include a first portion connected between the first linear trench and the second linear trench, and a second portion connected between the second linear trench and the third linear trench. A position of a connection point of the first portion of the separation trench and the second linear trench may be different from a position of a connection point of the second portion of the separation trench and the second linear trench in a longitudinal direction of the plurality of linear trenches.

This structure can suppress the occurrence of a processing failure at a connection point of trenches.

The embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

What is claimed is:

1. A semiconductor device comprising:
a semiconductor substrate;
a main upper electrode disposed on an upper surface of the semiconductor substrate;
a sense upper electrode disposed on the upper surface; and
a lower electrode disposed on a lower surface of the semiconductor substrate,
wherein
the semiconductor substrate comprises a main cell region and a sense cell region,
the upper surface in the main cell region comprises a main trench extending along a first direction from the main cell region to the sense cell region,
a main gate insulating layer and a main gate electrode are disposed in the main trench, the main gate electrode being insulated from the semiconductor substrate by the main gate insulating layer,
the main cell region comprises:
a main first semiconductor region being of a first conductive type and in contact with the main upper electrode and the main gate insulating layer; and
a main second semiconductor region being of a second conductive type and in contact with the main gate insulating layer at a lower side of the main first semiconductor region,
the upper surface in the sense cell region comprises a sense trench extending along the first direction,
a sense gate insulating layer and a sense gate electrode are disposed in the sense trench, the sense gate electrode being insulated from the semiconductor substrate by the sense gate insulating layer,
the sense cell region comprises:
a sense first semiconductor region being of the first conductive type and in contact with the sense upper electrode and the sense gate insulating layer; and
a sense second semiconductor region being of the second conductive type and in contact with the sense gate insulating layer at a lower side of the sense first semiconductor region,
the upper surface further comprises a separation trench extending along a second direction different from the first direction and separating the main second semiconductor region from the sense second semiconductor region,
a separation insulating layer is disposed in the separation trench, the separation insulating layer being in contact with the main second semiconductor region and the sense second semiconductor region, and
the semiconductor substrate further comprises:
a third semiconductor region being of the first conductive type, disposed across the main cell region and the sense cell region, being in contact with the main gate insulating layer at a lower side of the main second semiconductor region, being in contact with the sense gate insulating layer at a lower side of the sense second semiconductor region, being in contact with the separation insulating layer at a lower side of the main second semiconductor region, and being in contact with the separation insulating layer at a lower side of the sense second semiconductor region; and
a separation fourth semiconductor region being of the second conductive type, being in contact with a lower end of the separation insulating layer, and separated from the main second semiconductor region and the sense second semiconductor region by the third semiconductor region.

2. A semiconductor device of claim 1, wherein
the semiconductor substrate further comprises:
a main fourth semiconductor region being of the second conductive type, being in contact with a lower end of the main gate insulating layer, and separated from the main second semiconductor region by the third semiconductor region; and
a sense fourth semiconductor region being of the second conductive type, being in contact with a lower end of the sense gate insulating layer, and separated from the sense second semiconductor region by the third semiconductor region.

3. A semiconductor device of claim 1, wherein
a ring-shaped trench is formed on the upper surface, the ring-shaped trench extending so as to surround the sense cell region,
an insulating layer is disposed in the ring-shaped trench,
the semiconductor substrate further comprises a ring-shaped semiconductor region being of the second conductive type, being in contact with a lower end of the insulating layer in the ring-shaped trench, and extending along the ring-shaped trench,
the separation trench is a part of the ring-shaped trench,
the separation insulating layer is a part of the insulating layer in the ring-shaped trench, and
the separation fourth semiconductor region is a part of the ring-shaped semiconductor region.

4. A semiconductor device of claim 1, wherein
the main trench, the sense trench, and the separation trench are connected to each other, and
the main gate electrode and the sense gate electrode are connected to each other.

5. A semiconductor device of claim 1, wherein the semiconductor substrate is a SiC substrate having a hexagonal crystal structure having a c-axis extending along a thickness direction of the semiconductor substrate.

6. A semiconductor device of claim 1, wherein a semiconductor region being of the first conductive type and exposed on the upper surface is not disposed at a position being in contact with the separation insulating layer.

7. A semiconductor device of claim 1, wherein an electrode insulated from the semiconductor substrate by the separation insulating layer is disposed in the separation trench.

8. A semiconductor device of claim 1, comprising a plurality of the main trenches and a plurality of the sense trenches,
wherein the plurality of the main trenches and the plurality of the sense trenches are connected to each other to form a plurality of linear trenches,
the plurality of the linear trenches comprises:
a first linear trench;
a second linear trench adjacent to the first linear trench; and
a third linear trench adjacent to the second linear trench,
the separation trench comprises a first portion connected between the first linear trench and the second linear trench, and a second portion connected between the second linear trench and the third linear trench,
a position of a connection point of the first portion of the separation trench and the second linear trench is different from a position of a connection point of the second portion of the separation trench and the second linear trench in a longitudinal direction of the plurality of linear trenches.
